(19) United States
(12) Patent Application Publication
(10) Pub. No.: US 2024/0023261 A1
(43) Pub. Date: Jan. 18, 2024

(54) FOLDABLE DISPLAY APPARATUS

(71) Applicants: LG Display Co., Ltd., Seoul (KR); Fine M-Tec Co., LTD., Anyang-si (KR)

(72) Inventors: Jungkyu PARK, Seoul (KR); Jaekyu LEE, Anyang-si (KR); Chang Soo KIM, Paju-si (KR); TaeWoo KIM, Paju-si (KR); Eunae CHO, Gimpo-si (KR); SangJun LEE, Paju-si (KR)

(21) Appl. No.: 18/221,995

(22) Filed: Jul. 14, 2023

(30) Foreign Application Priority Data
Jul. 15, 2022 (KR) 10-2022-0087740

(51) Int. Cl. H05K 5/02; F16C 11/04

(52) U.S. Cl. CPC H05K 5/0226; F16C 11/04

(57) ABSTRACT

A foldable display apparatus is disclosed that comprises a first set housing and a second set housing and respectively supporting two different portions of a display panel; a sliding plate on an upper surface of one of the first set housing and the second set housing; a spring member applying pressure to the sliding plate such that the sliding plate moves in a direction that is dependent on a direction of folding of the foldable display apparatus; and a hinge assembly connected to the first set housing and the second set housing, the hinge assembly configured to fold the foldable display apparatus in a first direction and fold the foldable display apparatus in a second direction that is opposite the first direction.

### CROSS-REFERENCE TO RELATED APPLICATIONS

This application claims the priority of Republic of Korea Patent Application No. 10-2022-0087740 filed on Jul. 15, 2022, in the Korean Intellectual Property Office, which is incorporated by reference in its entirety.

### BACKGROUND

### Field

The present disclosure relates to a foldable display apparatus, and more particularly, to a foldable display apparatus having a hinge structure that is bidirectionally foldable.

### Description of the Related Art

Currently, portable terminals such as wireless terminals, personal digital assistants (PDAs), portable multimedia players (PMPs), and electronic notebooks tend to be miniaturized for portability. However, since a user of the portable terminal wants to receive various information such as text information, video, still image, MP3, and game through a screen of a portable terminal, the screen of the display unit is required to be large and wide. The miniaturization of the portable terminal brings about a reduction in the size of the screen of the display, which causes a limitation to satisfy both of the requirements.

To overcome the limitation, a flexible display apparatus such as a bendable display apparatus or a foldable display apparatus has recently been developed.

The flexible display apparatus may be implemented using a substrate made of a plastic material. Since the flexible display apparatus may be easily carried when folded and may realize a large screen when unfolded, it may be applied to various fields such as televisions and monitors in addition to mobile devices such as mobile phones, electronic books, and electronic newspapers.

### SUMMARY

An apparatus is disclosed that includes a hinge sed in an area where a display panel is folded, in order to implement a foldable display apparatus among flexible display apparatuses. The related art hinge structure is foldable in only one direction, and is difficult to simultaneously implement an in-folding having a display panel disposed therein and an out-folding having the display panel disposed thereout.

Even if a hinge capable of implementing in-folding and out-folding at the same time was applied, damage to the panel occurs during in-folding and damage to the display panel occurs during out-folding due to repeated folding implementations.

Accordingly, an object to be achieved by the present disclosure is to provide a bidirectional foldable display apparatus capable of implementing both in-folding and out-folding.

Another object to be achieved by the present disclosure is to provide a foldable display apparatus capable of resolving an occurrence of a damage to a display panel when pressure is applied to the display panel that is exposed when implementing out-folding.

Still another object to be achieved by the present disclosure is to provide a foldable display apparatus capable of solving a problem of reverse folding that happens due to buckling and creasing of a display panel caused by a recovery delay of an optically clear adhesive (OCA) when operating to an unfolding state from an out-folding state.

Another object to be achieved by the present disclosure is to provide a foldable display apparatus capable of relieving pressure applied to a display panel through movement of a set housing when in-folding and out-folding are implemented.

Another object to be achieved by the present disclosure is to provide a foldable display apparatus having excellent durability even in the repeated folding implementation.

Objects of the present disclosure are not limited to the above-mentioned objects, and other objects, which are not mentioned above, can be clearly understood by those skilled in the art from the following descriptions.

In one embodiment, a foldable display apparatus comprises: a first set housing configured to support a first portion of a display panel; a second set housing adjacent to the first set housing, the second set housing configured to support a second portion of the display panel; a sliding plate on an upper surface of one of the first set housing and the second set housing, the sliding plate in contact with one of the first portion or the second portion of the display panel; a spring member in contact with the sliding plate, the spring member configured to apply pressure to the sliding plate such that the sliding plate moves in a direction that is dependent on a direction of folding of the foldable display apparatus; a support member between the first set housing and the second set housing, the support member configured to support a third portion of the display panel that is between the first portion and the second portion of the display panel; a first insertion member between the first set housing and the support member; a second insertion member between the second set housing and the support member; and a hinge assembly connected to the first set housing and the second set housing, the hinge assembly configured to fold the foldable display apparatus in a first direction and fold the foldable display apparatus in a second direction that is opposite the first direction.

In one embodiment, a foldable display apparatus comprises: a display panel including a first portion and a second portion; a first set housing configured to support the first portion of a display panel; a second set housing adjacent to the first set housing and configured to support the second portion of the display panel, the second set housing including a recess; a sliding plate in the recess of the second set housing and connected to a part of the second portion of the display panel, the sliding plate having a first side that is spaced apart from an inner side of the recess and a second side that is spaced apart from an outer side of the recess while the foldable display apparatus is in an unfolded state; and a hinge assembly connected to the first set housing and the second set housing, the hinge assembly configured to fold the foldable display apparatus in a first direction from the unfolded state and fold the foldable display apparatus in a second direction from the unfolded state that is opposite the first direction.

According to the present disclosure, a bidirectional foldable display apparatus capable of being in-folding and out-folding may be implemented.

Other detailed matters of the exemplary embodiments are included in the detailed description and the drawings.

According to the present disclosure, problems such as buckling and creasing of a display panel, which occur when a folding is implemented, may be solved by disposing a sliding plate that is movable by pressure in a set housing.

According to the present disclosure, a reverse folding problem that occurs when out-folding is switched to unfolding may be solved.

According to the present disclosure, damage applied to a display panel may be minimized and reliability of a display apparatus may be improved even when repeated folding is implemented.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A is a perspective view illustrating an unfolding state of a foldable display apparatus according to an exemplary embodiment of the present disclosure;

FIG. 1B is a perspective view illustrating an in-folding state of a foldable display apparatus according to an exemplary embodiment of the present disclosure;

FIG. 1C is a perspective view illustrating an out-folding state of a foldable display apparatus according to an exemplary embodiment of the present disclosure;

FIG. 2A is a plan view illustrating a part of a configuration of a foldable display apparatus according to an exemplary embodiment of the present disclosure;

FIG. 2B is an exploded perspective view illustrating a part of a configuration of a foldable display apparatus according to an exemplary embodiment of the present disclosure;

FIG. 2C is an exploded perspective view illustrating an enlarged portion A of FIG. 2A according to an exemplary embodiment of the present disclosure;

FIGS. 3A and 3B are exploded perspective views illustrating a structure including a set housing and a sliding plate in a foldable display apparatus according to an exemplary embodiment of the present disclosure;

FIGS. 4A to 4C are perspective views illustrating movement of a sliding plate according to a folding movement in a foldable display apparatus according to an exemplary embodiment of the present disclosure;

FIGS. 5A to 5C are cross-sectional views illustrating movement of set housings according to an in-folding movement of a foldable display apparatus according to an exemplary embodiment of the present disclosure; and

FIGS. 6A to 6C are cross-sectional views illustrating movement of set housings according to an out-folding movement of a foldable display apparatus according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a foldable display apparatus according to exemplary embodiments of the present disclosure will be described in detail with reference to accompanying drawings.

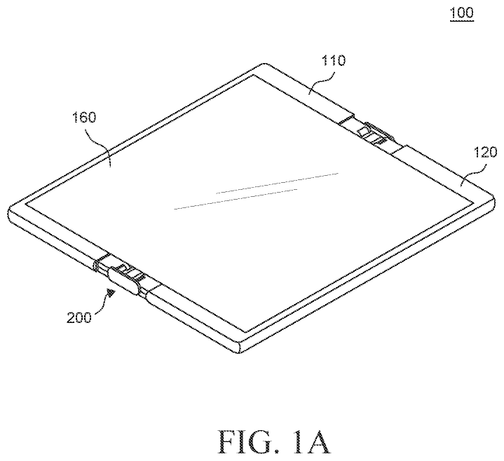

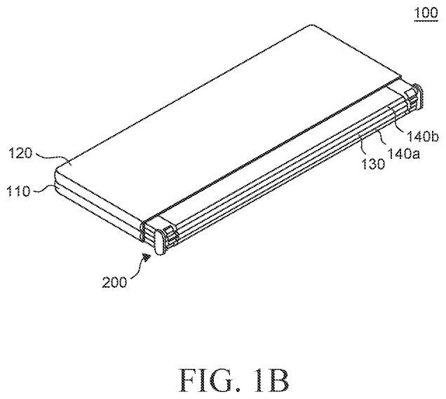

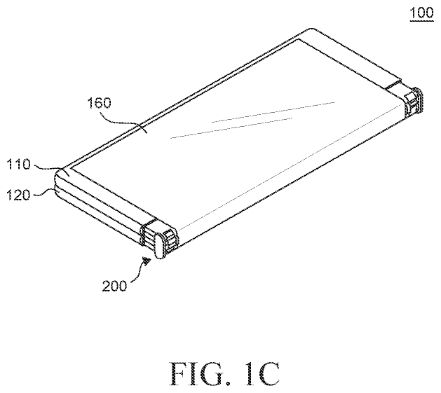

FIGS. 1A to 1C are views for explaining a foldable display apparatus according to an exemplary embodiment of the present disclosure.

FIGS. 1A to 1C are perspective views of a foldable display apparatus according to an exemplary embodiment of the present disclosure. FIG. 1A is a perspective view illustrating an unfolded state (e.g., a first state) of a foldable display apparatus 100 according to an exemplary embodiment of the present disclosure. FIG. 1B is a perspective view illustrating an in-folding state (e.g., a second state) of a foldable display apparatus 100 according to an exemplary embodiment of the present disclosure. The foldable display apparatus 100 is folded in a first direction from the unfolded state or from the out-folding state described below to reach the in-folding state. While in the in-folding state, the display panel 160 is an inner surface of the foldable display apparatus 100. FIG. 1C is a perspective view illustrating an out-folding state (e.g., a third state) of a foldable display apparatus according to an exemplary embodiment of the present disclosure. The foldable display apparatus 100 is folded in a second direction from the unfolded state or the in-folding state to reach the out-folding state where the second direction is opposite from the first direction. While in the out-folding state, the display panel 160 is an outer surface of the foldable display apparatus 100.

A foldable display apparatus 100 according to an exemplary embodiment of the present disclosure may be folded at a specific angle according to a user's intention. Also, the foldable display apparatus may be completely folded or unfolded according to the user's intention. The foldable display apparatus may also be folded or unfolded through in-folding (or inner-folding) so that a display panel is disposed therein, or may also be folded or unfolded through out-folding (or outer-folding) so that the display panel is disposed thereout. The foldable display apparatus is a bi-directional foldable display apparatus that is foldable bidirectionally to freely realize in-folding and out-folding according to the user's intention.

Referring to FIGS. 1A to 1C, a foldable display apparatus 100 according to an exemplary embodiment of the present disclosure may include a plurality of set housings including set housings 110 and 120, a hinge assembly 200, and a display panel 160.

FIGS. 1A to 1C briefly illustrate components of the foldable display apparatus for convenience of explanation, but various components for substantially operating the foldable display apparatus may be further included.

The set housings 110 and 120 are exterior covers of a set, and may support or accommodate various components of the foldable display apparatus 100 including the display panel 160. The set housings 110 and 120 may include a first set housing 110 on a left side of the foldable display apparatus 100 and a second set housing 120 on a right side of the foldable display apparatus 100, but are not limited thereto.

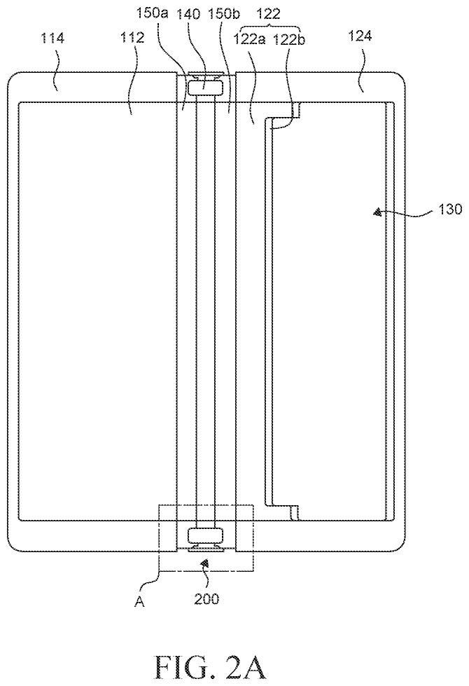

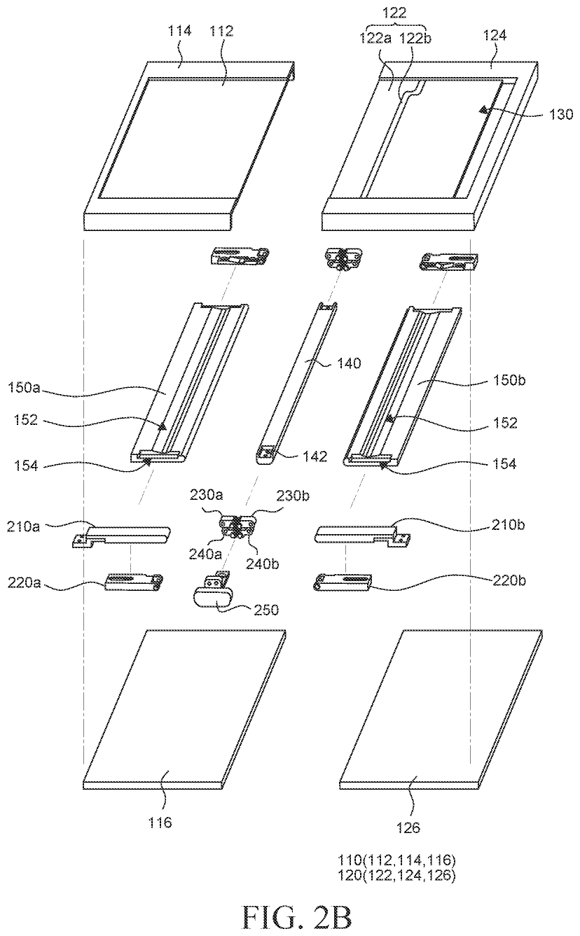

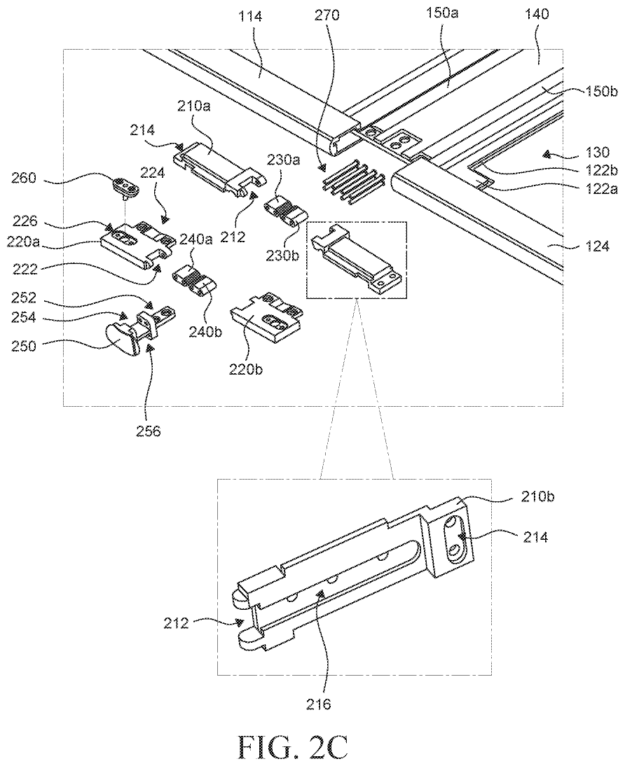

The first set housing 110 and the second set housing 120 may be spaced apart from each other with the hinge assembly 200 interposed therebetween. In addition, the first set housing 110 and the second set housing 120 may be disposed respectively on one area and another area where the foldable display apparatus 100 according to the exemplary embodiment of the present disclosure is folded and unfolded. That is, in the foldable display apparatus 100 according to the exemplary embodiment of the present disclosure, folding and unfolding movements may be performed by external force applied by a user based on an arbitrary area between the first set housing 110 and the second set housing 120. Detailed structures and functions of the set housings 110 and 120 will be described later with reference to FIGS. 2A to 2C.

The hinge assembly 200 is connected to the first set housing 110 and the second set housing 120 to implement folding and unfolding movements of the foldable display apparatus. Detailed structure and function of the hinge assembly will be described later with reference to FIGS. 2A to 2C.

The display panel 160 is disposed on the first set housing 110 and the second set housing 120. One of various display panels such as an organic light emitting display panel, and a liquid crystal display panel may be used as the display panel 160.

Although not illustrated in the drawings, the display panel 160 may include a plurality of sub pixels to display images to a user. In the display panel 160, a plurality of scan lines and a plurality of data lines may intersect with each other, and the plurality of sub pixels may be connected to the scan lines and the data lines, respectively. Among others, each of the plurality of sub pixels may be connected to a high-potential power line, a low-potential power line, an initialization signal line, and a light emitting control signal line.

A sub pixel is a minimum unit constituting a screen, and each of the plurality of sub pixels may include a light emitting diode and a pixel circuit for operating the light emitting diode. A plurality of light emitting diodes may be defined differently depending on a type of the display panel 160. For example, when the display panel 160 is an organic light emitting display panel, the light emitting diode may be an organic light emitting diode that includes an anode, an emission unit, and a cathode. Hereinafter, a description will be made on the assumption that the light emitting diode is an organic light emitting diode, but the type of light emitting diode is not limited thereto.

The pixel circuit is a circuit for controlling the driving of the light emitting diode. The pixel circuit may include, for example, a plurality of transistors and capacitors, but is not limited thereto.

In addition, the display panel 160 may have flexibility to be folded and unfolded along with the folding and unfolding of the foldable display apparatus 100.

The foldable display apparatus 100 may be folded to form a specific folding angle between the first set housing 110 and the second set housing 120. That is, although FIG. 1A shows that the first set housing 110 and the second set housing 120 are completely unfolded to have an angle of 180° therebetween, the foldable display apparatus 100 may be folded at a specific angle.

Also, in the foldable display apparatus 100, a specific folding angle may be maintained by a holding force applied from the hinge assembly 200. That is, the first set housing 110 and the second set housing 120 may be fixed by the hinge assembly 200 while maintaining the specific folding angle. Accordingly, the foldable display apparatus 100 may be folded at a specific angle according to the user's intention, and maintained in a folded state at the specific angle by the holding force from the hinge assembly 200.

Although not shown in the drawings, a bezel cover may cover a top bezel of the display panel 160 on a top surface of the display panel 160. The bezel cover may be integrally formed to cover the entire bezel of the display panel 160, but is not limited thereto. That is, the bezel cover may be configured to be separated into a first bezel cover on a left side and a second bezel cover on a right side.

Hereinafter, specific structures and functions of the foldable display apparatus according to the exemplary embodiment of the present disclosure will be described in detail with reference to FIGS. 2A to 2C.

FIG. 2A is a plan view illustrating a part of a configuration of a foldable display apparatus according to an exemplary embodiment of the present disclosure. FIG. 2B is an exploded perspective view illustrating a part of a configuration of a foldable display apparatus according to an exemplary embodiment of the present disclosure. FIG. 2C is an exploded perspective view illustrating an enlarged portion A of FIG. 2A.

Referring to FIGS. 2A and 2B, the set housings 110 and 120 include support bodies 112 and 122, frames 114 and 124, and covers 116 and 126, respectively. Specifically, the first set housing 110 includes a first support body 112, a first frame 114, and a first cover 116. The second set housing 120 includes a second support body 122, a second frame 124, and a second cover 126.

The first support body 112 and the second support body 122 may be base members for supporting various components of the foldable display apparatus 100 including the display panel 160. The first support body 112 and the second support body 122 may be disposed to be spaced apart from each other with a support member 140 therebetween.

Referring to FIGS. 2A and 2B, the first support body 112 of the first set housing 110 is configured as one substrate in a shape of a single layer without a step. In contrast, the second support body 122 of the second set housing 120 includes a first support area 122a and a second support area 122b that are stepped with each other. That is, a step is formed between the first support area 122a and the second support area 122b. The first support area 122a is located adjacent to the support member 140 and has the same height as the first support body 112 of the first set housing 110. The second support area 122b forms a step with the first support area 122a and has a lower height than the first support area 122a. Thus, the second support area 122b is a recess in the second set housing 120. The second support area 122b accommodates a sliding plate 130 to be described later. FIGS. 2A and 2B illustrate a structure in which the first support area 122a and the second support area 122b that are stepped with each other are formed in the second set housing 120, but the structure is not limited thereto. For example, both the first set housing 110 and the second set housing 120 may include the second support area for accommodating the sliding plate 130.

The first frame 114 and the second frame 124 are embedded frames of a set to surround and accommodate various components of the foldable display apparatus 100. The first frame 114 and the second frame 124 may surround edges of the first support body 112 and the second support body 122, respectively. Specifically, the first frame 114 surrounds three edges of the first support body 112 except for an edge facing the support member 140. In addition, the second frame 124 surrounds three edges of the second support body 122 except for an edge facing the hinge assembly 200.

The support body and the frame are manufactured separately to be assembled to each other, or may have a single structure to be integrally connected each other. In FIG. 2, it is illustrated that the first support body 112 and the first frame 114 are configured as a single structure to be integral each other, and the second support body 122 and the second frame 124 are configured as a single structure to be integral with each other, but the present disclosure is not limited thereto.

Fastening portions 270 coupled to the hinge assembly 200 may be formed in the first frame 114 and the second frame 124. For example, an accommodating portion in which a first upper link arm 210a (e.g., a first upper gear arm) and a second upper link arm 210b (e.g., a second upper gear arm) of the hinge assembly 200 may be inserted, and a fastening portion to be fastened to the first upper link arm 210a and the second upper link arm 210b may be formed inside the first frame 114 and the second frame 123, respectively, but the present disclosure is not limited thereto.

A first cover 116 and a second cover 126 are respectively disposed beneath the first support body 112 and the second support body 122. The first cover 116 and the second cover 126 may be surrounded and fixed by the first frame 114 and the second frame 124.

The first set housing 110 and the second set housing 120 may support components such as the display panel 160, and simultaneously accommodate structures such as insertion members. Specifically, the display panel 160 may be safely seated and supported in a space that is formed by the first support body 112, the second support body 122, the first frame 114, and the second frame 124. In addition, a receiving portion may be formed between the first cover 116 and the second cover 126 and the first support body 112 and the second support body 122 to accommodate a portion of the insertion members 150a and 150b.

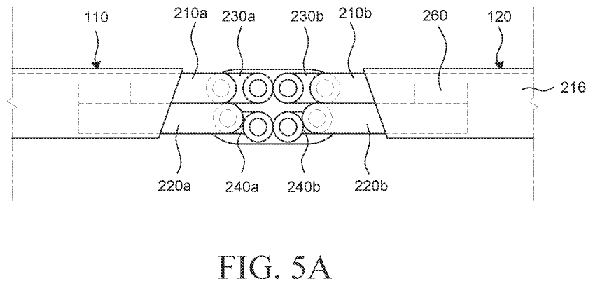

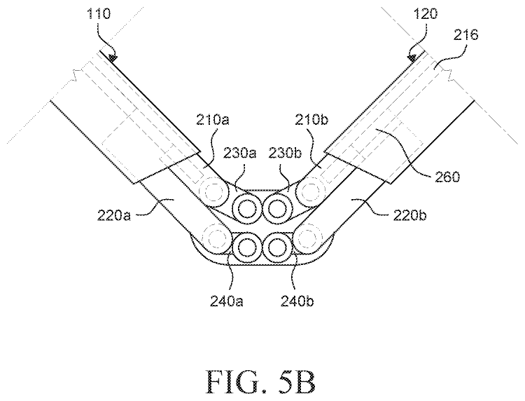

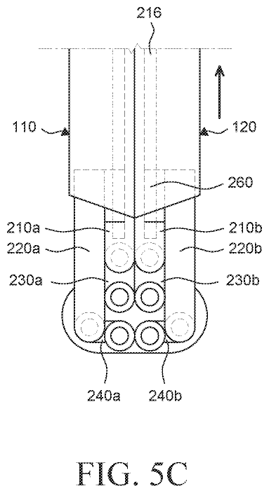

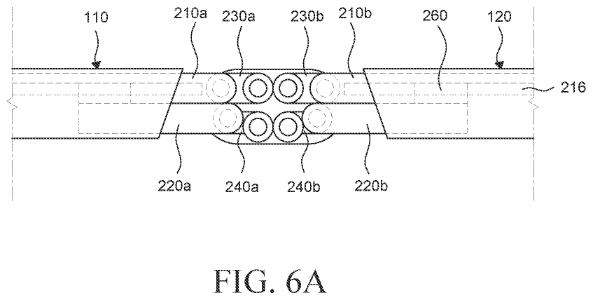

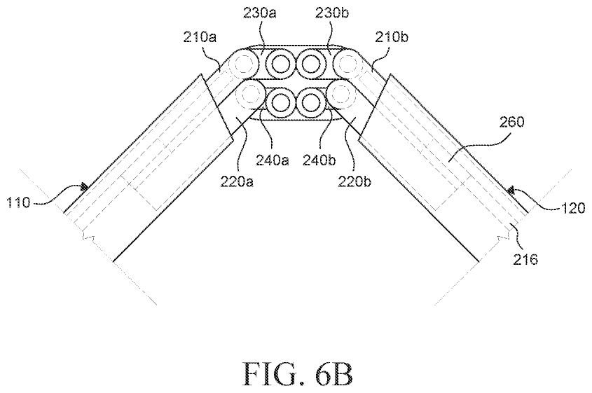

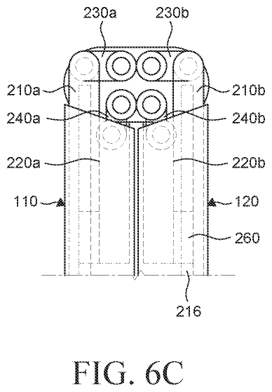

The first set housing 110 and the second set housing 120 may move in a widthwise direction according to a folding movement. The movement of the first set housing 110 and the second set housing 120 will be described later with reference to FIGS. 5A to 6C.

A sliding plate 130 is disposed in the second support area 122b of the second support body 122. The sliding plate 130 suppresses creasing of the display panel 160 by applying pressure to the display panel 160, and suppresses reverse folding of the display panel during in-folding and out-folding. Reverse folding is unintentional folding of the display panel in an opposite direction of the intended folding direction.

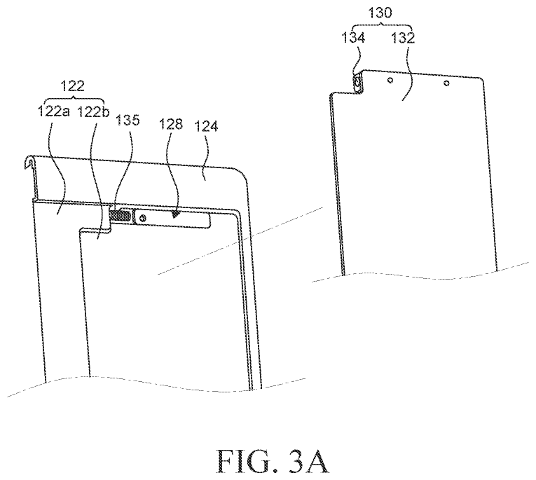

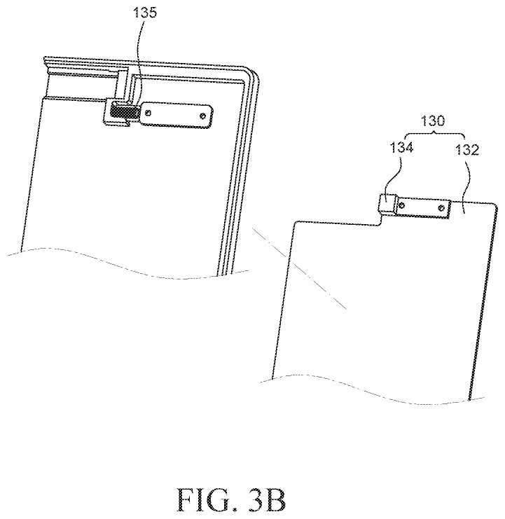

Hereinafter, a detailed description on the structure of the sliding plate will be given with reference to FIGS. 3A and 3B.

FIGS. 3A and 3B are exploded perspective views illustrating structures of a set housing and a sliding plate in a foldable display apparatus according to an exemplary embodiment of the present disclosure, viewed from top and rear surfaces, respectively.

First, the second set housing 120 further includes a groove 128 to be coupled to the sliding plate 130.

At this time, a spring member 135 configured to apply pressure to the sliding plate 130 is disposed in the groove 128. The spring member 135 applies pressure to the sliding plate 130 according to a folding movement so as to move the sliding plate 130. The spring member 135 may be disposed in a pre-contracted state to apply a fixed pressure to the sliding plate 130 in an unfolding state, but is not limited thereto.

The sliding plate 130 is disposed in the second set housing 120. Specifically, the sliding plate 130 is disposed to be placed in the second support area 122b, which is located at a lower position by forming a step, in the second support body 122. The sliding plate 130 has a width that is smaller than a width of the second support area 122b to have a margin in the second support area 122b in the widthwise direction. This may allow the sliding plate 130 to move left and right inside the second support area 122b. As an example, the sliding plate 130 may also have a length smaller than that of the second support area 122b to have a margin in the second support area 122b in the lengthwise direction, to facilitate the left and right movement of the sliding plate 130 by reducing the interference or friction on the sliding plate 130, without being limited thereto.

The sliding plate 130 includes a flat portion 132 and a protruding portion 134. The flat portion 132, as a support body, supports the display panel 160 located on an upper portion thereof, together with the second support body 122 of the second set housing 120. The protruding portion 134 is an area protruding toward a rear surface of the sliding plate 130 and is placed in the groove 128 formed in the second support body 122. The protruding portion 134 is brought into contact with the spring member 135 and receives pressure from the spring member 135 in the widthwise direction. As an example, the protruding portion 134 may be disposed on a portion of the flat portion 132 protruding toward an upper or lower direction as shown in FIG. 3A, or may be disposed on any position as long as it could be brought into contact with the spring member 135 and receives pressure from the spring member 135 in the widthwise direction.

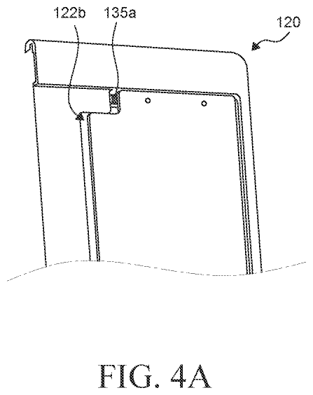

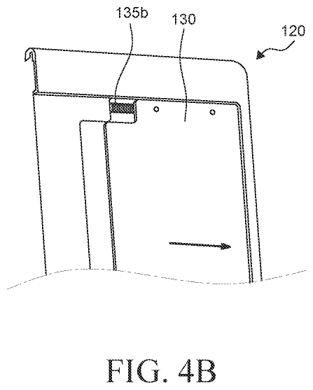

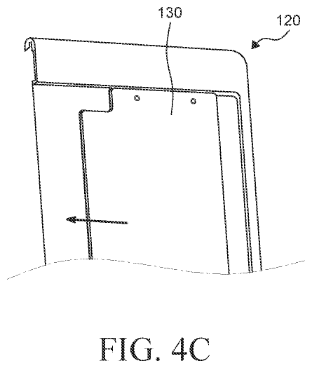

The position and movement of the sliding plate 130 according to the folding driving of the foldable display apparatus will be described later with reference to FIGS. 4A to 4C.

The support member 140 is interposed between the first set housing 110 and the second set housing 120. The support member 140 has a long plate shape in a longitudinal direction. The support member 140 has a flat upper surface to support the display panel 160. Referring to FIG. 2B, fastening portions 142 are formed in both side portions (e.g., end portions) of the support member 140 in the longitudinal direction to couple with fixing caps 250. The support member 140 is fixed to the fixing cap 250 through the fastening portion 142 so as to maintain a central shaft during a folding movement.

A first insertion member 150a and a second insertion member 150b are disposed on both sides of the support member 140. Referring to FIG. 2B, the first insertion member 150a and the second insertion member 150b have a long plate shape in the longitudinal direction. The first insertion member 150a and the second insertion member 150b may support the display panel 160 disposed thereon together with the support member 140. The first insertion member 150a and the second insertion member 150b may include a recess 152 extending in the longitudinal direction. The recess 152 forms a space in which the display panel may be disposed in a shape of “Q” during in-folding.

The first insertion member 150a and the second insertion member 150b are provided with fastening portions 154, to which a first lower link arm 220a (e.g., a first lower gear arm) and a second lower link arm 220b (e.g., a second lower gear arm) constituting the hinge assembly 200 may be coupled, respectively. The first insertion member 150a and the second insertion member 150b may move into the first set housing 110 and the second set housing 120 along with movement of the first lower link arm 220a and the second lower link arm 220b.

The hinge assembly 200 is connected to the first set housing 110 and the second set housing 120 to implement folding and unfolding movements of the foldable display apparatus.

Referring to FIGS. 2B and 2C, the hinge assembly 200 may include upper link arms, lower link arms, upper gears, lower gears, sliding connection members 260, a plurality of process pins, and fixing caps 250.

A first upper gear 230a and a second upper gear 230b allow movement of a first upper link arm 210a and a second upper link arm 210b connected to the first set housing 110 and the second set housing 120, respectively. The first upper gear 230a and the second upper gear 230b each have a two-shaft gear shape including a tooth portion at a first end of the upper gear and a connecting portion at a second end of the upper gear that is opposite the first end. The first upper gear 230a and the second upper gear 230b may rotate while the tooth portions thereof are engaged with each other. The connecting portions of the first upper gear 230a and the second upper gear 230b are connected to the first upper link arm 210a and the second upper link arm 210b, respectively. Centers of the connecting portions serve as rotational shafts for rotation of the first upper link arm 210a and the second upper link arm 210b.

The first upper gear 230a and the second upper gear 230b may include holes formed in the rotational shafts of the tooth portions and the connecting portions. The first upper gear 230a and the second upper gear 230b may be connected to process caps through the holes of the tooth portions, and fastened to coupling shafts of the first upper link arm 210a and the second upper link arm 210b through the holes of the connecting portions.

The rotational shafts of the tooth portions and the connecting portions of the first upper gear 230a and the second upper gear 230b may all be located on the same plane.

A first lower gear 240a and a second lower gear 240b are disposed beneath the first upper gear 230a and the second upper gear 230b, respectively. The first lower gear 240a and the second lower gear 240b allow movement of a first lower link arm 220a and a second lower link arm 220b connected to the first upper link arm 210a and the second upper link arm 210b, respectively. The first lower gear 240a and the second lower gear 240b each have a two-shaft gear shape including a tooth portion and a connecting portion. The first lower gear 240a and the second lower gear 240b may rotate while the tooth portions thereof are engaged with each other. The connecting portions of the first lower gear 240a and the second lower gear 240b are connected to the first lower link arm 220a and the second lower link arm 220b, respectively. Centers of the connecting portions serve as rotational shafts for rotation of the first lower link arm 220a and the second lower link arm 220b.

The first lower gear 240a and the second lower gear 240b may form holes in the rotational shafts of the respective tooth portions and the connecting portions. The first lower gear 240a and the second lower gear 240b may be connected to the fixing caps 250 through the holes of the tooth portions, and fastened to coupling shafts 222 of the first lower link arm 220a and the second lower link arm 220b through the holes of the connecting portions.

The rotational shafts of the respective tooth portions and the connecting portions of the first lower gear 240a and the second lower gear 240b may be located on different planes from each other. The rotational shafts of the tooth portion and the connecting portion of the first upper gear 230a are all located on the same plane as the rotational shafts of the tooth portion and the connecting portion of the second upper gear 230b. On the contrary, the rotational shafts of the tooth portions of the first lower gear 240a and the second lower gear 240b may be located on a different plane from the rotational shafts of the connecting portions of the first lower gear 240a and the second lower gear 240b. Through this, the first upper link arm 210a and the second upper link arm 210b connected to the first upper gear 230a and the second upper gear 230b may behave differently from the first lower link arm 220a and the second lower link arm 220b connected to the first lower gear 240a and the second lower gear 240b.

The first upper link arm 210a and the second upper link arm 210b are respectively disposed on both sides of the first upper gear 230a and the second upper gear 230b. The first upper link arm 210a and the second upper link arm 210b connect the hinge assembly 200, the first set housing 110, and the second set housing 120 such that the first set housing 110 and the second set housing 120 are folded and unfolded based on the hinge assembly 200.

Referring to FIG. 2C, each of the first upper link arm 210a and the second upper link arm 210b includes a coupling shaft 212, a fastening portion 214, and a guide portion 216. The coupling shafts 212 of the first upper link arm 210a and the second upper link arm 210b are connected to the connecting portions of the first upper gear 230a and the second upper gear 230b, respectively. Accordingly, the first upper link arm 210a and the second upper link arm 210b may rotate, in response to the first upper gear 230a and the second upper gear 230b rotating centering on the pair of rotational shafts.

The fastening portions 214 of each of the first upper link arm 210a and the second upper link arm 210b may be fastened to a fastening portion formed in the first frame 114 of the first set housing 110 and a fastening portion formed in the second frame 124 of the second set housing 120. This may allow the set housings and other components accommodated in the set housings to be folded and unfolded depending on whether the hinge assembly 200 is operated. Although not illustrated in FIG. 2C, the first upper link arm 210a and the second upper link arm 210b may be fixedly inserted into the accommodating portions of the first frame 114 and the second frame 124 so as to be connected to the fastening portions which are located inside the accommodating portions of the first frame 114 and the second frame 124.

The guide portions 216 of each of the first upper link arm 210a and the second upper link arm 210b are located in rear surfaces of the first and second upper link arms. The first lower link arm 220a and the second lower link arm 220b are connected to the first upper link arm 210a and the second upper link arm 210b, respectively, through the guide portions 216, so as to perform sliding movement. In FIG. 2C, the guide portions 216 of the first upper link arm 210a and the second upper link arm 210b may be fastened to sliding connection members 260 that are connected to the first lower link arm 220a and the second lower link arm 220b, respectively.

The first lower link arm 220a and the second lower link arm 220b are located beneath the first upper link arm 210a and the second upper link arm 210b. The first lower link arm 220a and the second lower link arm 220b are respectively disposed on both sides of the first lower gear 240a and the second lower gear 240b. The first lower link arm 220a and the second lower link arm 220b may be fastened to the first upper link arm 210a and the second upper link arm 210b so as to perform sliding movement.

Referring to FIG. 2C, each of the first lower link arm 220a and the second lower link arm 220b includes a coupling shaft 222, a fastening portion 224, and a fixing portion 226. The coupling shafts 222 of the first lower link arm 220a and the second lower link arm 220b are respectively connected to the connecting portions of the first lower gear 240a and the second lower gear 240b. Accordingly, the first lower link arm 220a and the second lower link arm 220b may rotate, in response to the first lower gear 240a and the second lower gear 240b rotating centering on the pair of rotational shafts.

The fastening portions 224 of the first lower link arm 220a and the second lower link arm 220b may be fastened to the fastening portions 154 of the first insertion member 150a and the second insertion member 150b, respectively, such that the first insertion member 150a and the second insertion member 150b are folded or unfolded depending on whether the hinge assembly 200 is operated.

The fixing portions 226 of each of the first lower link arm 220a and the second lower link arm 220b are located in top surfaces of the first and second lower link arms. The fixing portions 226 enable the first lower link arm 220a and the second lower link arm 220b to be connected to the first upper link arm 210a and the second upper link arm 210b, respectively, so as to perform sliding movement. Specifically, the sliding connection members 260 may be fastened to the fixing portions 226 of the first lower link arm 220a and the second lower link arm 220b, respectively. The sliding connection members 260 may be inserted into the guide portions 216 of the first upper link arm 210a and the second upper link arm 210b, respectively, so as to perform sliding movement. FIG. 2C illustrates the structure in which the separate sliding connection members 260 are fastened to the fixing portions 226 of the first lower link arm 220a and the second lower link arm 220b. However, the fixing portions 226 of the first lower link arm 220a and the second lower link arm 220b are implemented to protrude outward, without the separate sliding connection members 260. Accordingly, a structure in that the guide portions 216 of each of the first upper link arm 210a and the second upper link arm 210b are fastened is also possible.

The fixing cap 250 fixes (connects together) the first upper gear 230a, the second upper gear 230b, the first lower gear 240a, the second lower gear 240b, and the support member 140. The fixing cap 250 includes a first fastening portion 252, a second fastening portion 254, and a third fastening portion 256. The first fastening portion 252 of the fixing cap 250 has a shape extending into the display apparatus and may be fixedly fastened to the fastening portion 142 of the support member 140. The second fastening portion 254 of the fixing cap 250 accommodates the first upper gear 230a and the second upper gear 230b, and may be fastened through the holes formed in the tooth portions of the first upper gear 230a and the second upper gear 230b, respectively. The third fastening portion 256 of the fixing cap 250 accommodates the first lower gear 240a and the second lower gear 240b, and may be fastened through the holes formed in the tooth portions of the first lower gear 240a and the second lower gear 240b, respectively.

Hereinafter, structure and movement of the sliding plate 130 when the foldable display apparatus 100 is folded and unfolded will be described in detail with reference to FIGS. 4A to 4C.

FIGS. 4A to 4C are perspective views illustrating movement of a sliding plate according to a folding movement in a foldable display apparatus according to an exemplary embodiment of the present disclosure.

FIG. 4A illustrates a position of the sliding plate 130 when the foldable display apparatus is in an unfolded state, that is, when the first set housing 110 and the second set housing 120 are fully unfolded to form an angle of 180° therebetween.

Referring to FIG. 4A, the sliding plate 130 is disposed to have a fixed margin on left and right sides within the second support area 122b. That is, the sliding plate 130 has a first side that is spaced apart from an inner side (e.g., the left side) of the recess in the second support body 122 and a second side that is spaced apart from an outer side (e.g., the right side) of the recess in the second support body 122 that is opposite the inner side while the foldable display apparatus 100 is in the unfolded state. In this case, a spring member 135a is compressed by a predetermined amount. This may be implemented by compressing the spring member 135a by a predetermined amount, disposing the sliding plate 130 to be located in a central portion of the second support area 122b, and then adhering the display panel onto the sliding plate 130, during a process of manufacturing the foldable display apparatus. Accordingly, in an unfolded state, the sliding plate 130 receives pressure from the spring member 135a.

FIG. 4B illustrates a position of the sliding plate 130 when the foldable display apparatus is in an in-folding state, that is, when the first set housing 110 and the second set housing 120 are fully folded so as to dispose the display panel therein.

Referring to FIG. 4B, the sliding plate 130 moves outward within the second support area 122b. The compressed spring member 135b pressurizes the sliding plate 130 to be pushed outwardly during an in-folding process. As the sliding plate 130 moves outward toward the outer side of the recess (e.g., second support area 122b) in the second support body 122, creasing of the display panel corresponding to a folding area may be suppressed as the sliding plate 130 tensions the display panel in the outward direction by moving in the outward direction of the arrow in FIG. 4B.

FIG. 4C illustrates a position of the sliding plate 130 when the foldable display apparatus is in an out-folding state, that is, when the first set housing 110 and the second set housing 120 are fully folded back such that the display panel is disposed outside.

Referring to FIG. 4C, the sliding plate 130 moves inward within the second support area 122b toward the inner side of the second support area 122B (e.g., the recess). This results from an application of attractive force to the display panel due to an increase in radius of curvature of the folding area during an out-folding process. As the sliding plate 130 moves inward, the spring member may be compressed more than that the unfolding state.

On the other hand, when the out-folding state illustrated in FIG. 4C is operating to the unfolded state illustrated in FIG. 4A, a recovery delay of an adhesive between the display panel and the set housings causes buckling and creasing of the display panel corresponding to the folding area. Accordingly, a reverse folding in that the display panel is out-folded again by the buckling or creasing of the display panel may occur. In the foldable display apparatus according to the exemplary embodiment of the present disclosure, a fixed pressure may be applied to the display panel using the spring member 135b and the sliding plate 130. That is, when the out-folding state is operating to the unfolded state, as illustrated in FIG. 4A, since the margin as much as a predetermined distance exists outside the sliding plate 130, the spring member 135b which is compressed by the predetermined amount in the unfolded state moves the sliding plate outward. This may suppress forming creases on the display panel as the sliding plate 130 tensions the display panel in the inward direction by moving in the inward direction of the arrow in FIG. 4C.

Hereinafter, structure and movement of the sliding plate when the foldable display apparatus is folded and unfolded will be described in detail with reference to FIGS. 5A to 5C.

FIGS. 5A to 5C are cross-sectional views of movement of set housings according to an in-folding movement of a foldable display apparatus according to an exemplary embodiment of the present disclosure.

Referring to FIG. 5A, the upper link arms 210a and 210b and the lower link arms 220a and 220b are inserted into the first set housing 110 and the second set housing 120. The lower link arms 220a and 220b are fastened to the guide portions 216 of the upper link arms 210a and 210b through the sliding connection members 260.

Thereafter, referring to FIGS. 5B and 5C, an in-folding is implemented by folding the first set housing 110 and the second set housing 120 upward. At this time, during the in-folding, the lower gears 240a and 240b are fixed and the lower link arms 220a and 220b rotate upward centering on the central shafts of the connecting portions of the lower gears 240a and 240b. The connecting portions of the upper gears 230a and 230b rotate upward with respect to the tooth portions as central shafts, and the upper link arms 210a and 210b rotate upward centering on the central shafts of the connection portions. At this time, the lower link arms 220a and 220b slide along the guide portion 216 of the upper link arms 210a and 210b, and the set housings 110 and 120 fixed to the upper link arms 210a and 210b slide in a direction away from the lower gears 240a and 240b.

As such, in the foldable display apparatus 100 according to the exemplary embodiment of the present disclosure, as the set housings slide away from the lower gears and the shafts of the lower gears during the in-folding, tension may be maintained on the display panel. That is, the set housings slide away from the hinge assembly during folding in the first direction to implement the in-folding. This may suppress forming creases on the display panel corresponding to the folding area.

FIGS. 6A to 6C are cross-sectional views illustrating movement of a set housing according to an out-folding movement of a foldable display apparatus 100 according to an exemplary embodiment of the present disclosure.

Referring to FIGS. 6B and 6C, out-folding is implemented by folding the first set housing 110 and the second set housing 120 downward. At this time, during the out-folding, the upper gears 230a and 230b are fixed and the upper link arms 210a and 210b rotate downward centering on the central shafts of the connecting portions of the upper gears 230a and 230b. The connecting portions of the lower gears 240a and 240b rotate downward centering on the tooth portions, and the lower link arms 220a and 220b rotate downward centering on the central shafts of the connecting portions of the lower gears 240a and 240b. At this time, the lower link arms 220a and 220b slide along the guide portion 216 of the upper link arms 210a and 210b, and the set housings 110 and 120 fixed to the upper link arms 210a and 210b slide in a direction closer to the upper gears 230a and 230b.

As such, in the foldable display apparatus according to the exemplary embodiment of the present disclosure, the set housings slide in a direction closer to the lower gears and the shafts of the lower gears during the out-folding. That is, the set housings slide toward the hinge assembly during folding in the second direction to implement the out-folding.

As confirmed in FIGS. 5A to 6C, the foldable display apparatus according to the exemplary embodiment of the present disclosure may implement out-folding and in-folding. In particular, in the process of switching from the out-folding state illustrated in FIG. 6C to the in-folding state illustrated in FIG. 5C, the recovery delay of the adhesive between the display panel and the set housings may cause buckling and creasing of the display panel corresponding to the folding area. However, as illustrated in FIG. 6C, the set housings may move in a direction away from the gears during the in-folding, compared to the out-folding, and accordingly, outward tension may be applied to the display panel. That is, the set housings slide away from the hinge assembly during folding in the first direction to implement the in-folding and the set housings slide towards the hinge assembly during folding the second direction to implement the out-folding. Therefore, in the process of switching from the out-folding to the in-folding, the display panel may maintain tension, thereby suppressing appearance of creases on the display panel.

The exemplary embodiments of the present disclosure can also be described as follows:

According to an aspect of the present disclosure, there is provided a foldable display apparatus. The foldable display apparatus comprises a first set housing and a second set housing arranged adjacent to each other and respectively supporting two different portions of a display panel; a sliding plate disposed on an upper surface of at least one of the first set housing and the second set housing; a spring member transmitting pressure to the sliding plate so that the sliding plate moves outward; a support member disposed between the first set housing and the second set housing and supporting the display panel; a first insertion member disposed between the first set housing and the support member; a second insertion member disposed between the second set housing and the support member; and a hinge assembly connecting the first set housing and the second set housing and configured to folding and unfolding movements of the first set housing and the second set housing.

Each of the first set housing and the second set housing may include a cover located beneath the display panel; a support body disposed on the cover; a frame surrounding the support body and the cover; a support portion formed on the support body such that the display panel is placed thereon; and a receiving portion formed between the support body and the cover to accommodate at least portions of the first insertion member and the second insertion member.

The support body may include a first support area and a second support area located at a lower height than the first support area to form a step, and the sliding plate may be disposed in the second support area and has a narrower width than the second support area.

The support body further may include a groove in which a protruding portion formed on a rear surface of the sliding plate is accommodated so as to fix the sliding plate, and the spring member may be disposed in the groove.

The spring member may be compressed by a predetermined amount in an unfolding state in which the first set housing and the second set housing are unfolded to form an angle of 180° therebetween, and the sliding plate may be disposed to have margins on both inner and outer sides within the second support area.

The hinge assembly may comprise a first upper gear and a second upper gear including tooth portions engaged with each other and connecting portions located outside the tooth portions, respectively; a first lower gear and a second lower gear disposed beneath the first upper gear and the second upper gear, and including tooth portions engaged with each other, and connecting portions located outside the tooth portions, respectively; a first upper link arm and a second upper link arm fastened to the connecting portions of the first upper gear and the second upper gear, respectively; and a first lower link arm and a second lower link arm fastened to the connecting portions of the first lower gear and the second lower gear, respectively. The first upper link arm and the second upper link arm may be fixedly fastened to the first set housing and the second set housing, respectively, and the first lower link arm and the second lower link arm may be fastened to the first insertion member and the second insertion member, respectively.

The first upper link arm and the second upper link arm may further include guide portions formed on rear surfaces thereof, respectively, and the first lower link arm and the second lower link arm may be connected to the guide portions of the first upper link arm and the second upper link arm, respectively, to perform sliding movement.

The foldable display apparatus may further comprise a fixing cap fastened to the support member and accommodating the first upper gear, the second upper gear, the first lower gear, and the second lower gear.

The first set housing and the second set housing may slide away from the first lower gear and the second lower gear during an in-folding movement in which the display panel is disposed therein.

The sliding plate slides outward during an in-folding movement in which the display panel may be disposed therein.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A foldable display apparatus comprising:
a first set housing configured to support a first portion of a display panel;
a second set housing adjacent to the first set housing, the second set housing configured to support a second portion of the display panel;
a sliding plate on an upper surface of one of the first set housing and the second set housing, the sliding plate in contact with one of the first portion or the second portion of the display panel;
a spring member in contact with the sliding plate, the spring member configured to apply pressure to the sliding plate such that the sliding plate moves in a direction that is dependent on a direction of folding of the foldable display apparatus;
a support member between the first set housing and the second set housing, the support member configured to support a third portion of the display panel that is between the first portion and the second portion of the display panel;
a first insertion member between the first set housing and the support member;
a second insertion member between the second set housing and the support member; and
a hinge assembly connected to the first set housing and the second set housing, the hinge assembly configured to fold the foldable display apparatus in a first direction and fold the foldable display apparatus in a second direction that is opposite the first direction.

2. The foldable display apparatus according to claim 1, wherein each of the first set housing and the second set housing includes:
a cover beneath the display panel;
a support body on the cover, the display panel on the support body;
a frame surrounding the support body and the cover; and
a receiving portion between the support body and the cover, at least portions of the first insertion member and the second insertion member positioned in the receiving portion.

3. The foldable display apparatus according to claim 2, wherein the support body of one of the first set housing or the second support housing includes a first support area at a first height and a second support area at a second height that is lower than the first height such that a step is between the first support area and the second support area, and the sliding plate is in the second support area and has a width that is less than a width of the second support area.

4. The foldable display apparatus according to claim 3, wherein the support body further includes a groove and the spring member is in the groove, and a protruding portion that protrudes from a rear surface of the sliding plate is in the groove to connect the sliding plate to the support body.

5. The foldable display apparatus according to claim 4, wherein the spring member is compressed by a predetermined amount in an unfolded state of the foldable display apparatus in which an angle of 180° is between the first set housing and the second set housing, and the sliding plate is spaced apart from an inner side of the second support area and an outer side of the second support area while the foldable display apparatus is in the unfolded state.

6. The foldable display apparatus according to claim 1, wherein the hinge assembly comprises:
a first upper gear including first tooth portions at a first end of the first upper gear and a first connection portion at a second end of the first upper gear that is opposite the first end of the first upper gear;
a second upper gear including second tooth portions at a first end of the second upper gear and a second connection portion at a second end of the second upper gear that is opposite the first end of the second upper gear, the second tooth portions engaged with the first tooth portions of the first upper gear;
a first lower gear that overlaps the first upper gear and includes first tooth portions at a first end of the first lower gear and a first connection portion at a second end of the first lower gear that is opposite the first end of the first lower gear;
a second lower gear that overlaps the second upper gear and includes second tooth portions at a first end of the second lower gear and a second connection portion at a second end of the second lower gear that is opposite the first end of the second lower gear, the second tooth portions of the second lower gear engaged with the first tooth portions of the first lower gear;
a first upper link arm connected to the first connection portion of the first upper gear;
a second upper link arm connected to the second connection portion of the second upper gear; and
a first lower link arm connected to the first connection portion of the first lower gear;
a second lower link arm connected to the second connection portion of the second lower gear,
wherein the first upper link arm is connected to the first set housing and the second upper link arm is connected to second set housing, and the first lower link arm is connected to the first insertion member and the second lower link arm is connected to the second insertion member.

7. The foldable display apparatus according to claim 6, wherein the first upper link arm further includes a first guide portion on a rear surface of the first upper link arm and the second upper link arm further includes a second guide portion on a rear surface of the second upper link arm, and the first lower link arm is connected to the first guide portion of the first upper link arm such that the first lower link arm slides along the first guide portion, and the second lower link arm is connected to the second guide portion of the second upper link arm such that the second lower link arm slides along the second guide portion.

8. The foldable display apparatus according to claim 6, further comprising:
a fixing cap connected to the support member, and the first upper gear, the second upper gear, the first lower gear, and the second lower gear are connected to the fixing cap.

9. The foldable display apparatus according to claim 7, wherein the first set housing and the second set housing are configured to slide away from the first lower gear and the second lower gear during folding in the first direction, and the first set housing and the second set housing are configured to slide toward the first lower gear and the second lower gear during folding in the second direction.

10. The foldable display apparatus according to claim 5, wherein the sliding plate slides towards the outer side of the second support member during folding in the first direction, and the sliding plate slides towards the inner side of the second support member during folding in the second direction.

11. The foldable display apparatus of claim 1, wherein the display panel is an inner surface of the foldable display apparatus responsive to folding in the first direction, and the display panel is an outer surface of the foldable display apparatus responsive to folding in the second direction.

12. A foldable display apparatus, comprising:
a display panel including a first portion and a second portion;
a first set housing configured to support the first portion of a display panel;
a second set housing adjacent to the first set housing and configured to support the second portion of the display panel, the second set housing including a recess;
a sliding plate in the recess of the second set housing and connected to a part of the second portion of the display panel, the sliding plate having a first side that is spaced apart from an inner side of the recess and a second side that is spaced apart from an outer side of the recess while the foldable display apparatus is in an unfolded state; and
a hinge assembly connected to the first set housing and the second set housing, the hinge assembly configured to fold the foldable display apparatus in a first direction from the unfolded state and fold the foldable display apparatus in a second direction from the unfolded state that is opposite the first direction.

13. The foldable display apparatus of claim 12, wherein in the unfolded state of the foldable display apparatus an angle of 180° is between the first set housing and the second set housing, and the display panel is an inner surface of the foldable display apparatus responsive to folding in the first direction from the unfolded state, and the display panel is an outer surface of the foldable display apparatus responsive to folding in the second direction from the unfolded state.

14. The foldable display apparatus of claim 13, wherein the sliding plate is configured to slide towards the outer side of the recess responsive to the foldable display apparatus folding in the first direction from the unfolded state, and the sliding plate is configured to slide towards the inner side of the recess responsive to the foldable display apparatus folding in the second direction from the unfolded state.

15. The foldable display apparatus of claim 13, wherein the first set housing and the second set housing are configured to slide away from the hinge assembly during folding in the first direction, and the first set housing and the second set housing are configured to slide toward the hinge assembly during folding in the second direction.

16. The foldable display apparatus of claim 13, further comprising:
a spring in contact with the sliding plate, the spring member is compressed and applies pressure to the sliding plate while the foldable display apparatus is in the unfolded state.

17. The foldable display apparatus of claim 16, wherein the second set housing includes a groove and the spring is in the groove, and the sliding plate includes a protrusion that protrudes from a rear surface of the sliding plate and is in the groove to connect the sliding plate to the second set housing.

18. The foldable display apparatus of claim 12, further comprising:
a support member between the first set housing and the second set housing, the support member configured to support a third portion of the display panel that is between the first portion and the second portion of the display panel;
a first insertion member between the first set housing and the support member; and
a second insertion member between the second set housing and the support member.

19. The foldable display apparatus of claim 18, wherein the hinge assembly comprises:
a first upper gear including first tooth portions at a first end of the first upper gear and a first connection portion at a second end of the first upper gear that is opposite the first end of the first upper gear;
a second upper gear including second tooth portions at a first end of the second upper gear and a second connection portion at a second end of the second upper gear that is opposite the first end of the second upper gear, the second tooth portions engaged with the first tooth portions of the first upper gear;
a first lower gear that overlaps the first upper gear and includes first tooth portions at a first end of the first lower gear and a first connection portion at a second end of the first lower gear that is opposite the first end of the first lower gear;
a second lower gear that overlaps the second upper gear and includes second tooth portions at a first end of the second lower gear and a second connection portion at a second end of the second lower gear that is opposite the first end of the second lower gear, the second tooth portions of the second lower gear engaged with the first tooth portions of the first lower gear;
a first upper link arm connected to the first connection portion of the first upper gear;
a second upper link arm connected to the second connection portion of the second upper gear;
a first lower link arm connected to the first connection portion of the first lower gear;
a second lower link arm connected to the second connection portion of the second lower gear,
wherein the first upper link arm is connected to the first set housing and the second upper link arm is connected to second set housing, and the first lower link arm is connected to the first insertion member and the second lower link arm is connected to the second insertion member.

20. The foldable display apparatus according to claim 19, wherein the first upper link arm further includes a first guide portion on a rear surface of the first upper link arm and the second upper link arm further includes a second guide portion on a rear surface of the second upper link arm, and the first lower link arm is connected to the first guide portion of the first upper link arm such that the first lower link arm slides along the first guide portion, and the second lower link arm is connected to the second guide portion of the second upper link arm such that the second lower link arm slides along the second guide portion.
